(19) United States
(12) Patent Application Publication
(10) Pub. No.: US 2026/0309414 A1
(43) Pub. Date: Oct. 8, 2026

(54) DEHUMIDIFYING MODULE, WAFER PROCESSING APPARATUS

(71) Applicant: EBARA CORPORATION, Tokyo (JP)

(72) Inventor: Kotaro TOYOSAWA, Tokyo (JP)

(21) Appl. No.: 19/637,433

(22) Filed: Apr. 2, 2026

(30) Foreign Application Priority Data
Apr. 7, 2025 (JP) 2025-063002

(51) Int. Cl. F26B 21/00; H10P 72/00

(52) U.S. Cl. CPC F26B 21/002; H10P 72/0406

(57) ABSTRACT

To restrain dew condensation from occurring within an exhaust duct of equipment that uses a wafer processing apparatus configured to process a wafer with liquid. One embodiment discloses a dehumidifying module disposed downstream of a processing module that processes a wafer with liquid, the dehumidifying module including a cooling tank connected to a downstream side of the processing module, a heat exchanger disposed inside the cooling tank, a jet cooler, and a first cold air pipe connecting a refrigerant inlet of the heat exchanger and a cold air outlet of the jet cooler.

### TECHNICAL FIELD

The present application relates to dehumidifying modules and wafer processing apparatus including dehumidifying modules. In an example, the application relates to a wafer cleaning device by which a cleaning processing is applied to a wafer, such as a semiconductor wafer, while feeding a process liquid to the wafer, and a dehumidifying module that is connected to the wafer cleaning device. The wafer cleaning device and the dehumidifying module according to the example are applied to the process of fabricating flat panel displays and the process of fabricating image sensors, such as CMOS and CCD image sensors, as well as the process of fabricating memory and logic devices for semiconductors.

### BACKGROUND ART

In the process of fabricating conductor devices, various films having different properties are formed on silicon wafers. These films are subjected to various kinds of processings, and thus microwirings are formed. In a damascene process, for example, wiring gutters are formed in the films, and metal, such as copper, is fitted in the wiring gutters. Chemical mechanical polishing (CMP) is then performed to remove excess metal, to thereby form metal wiring. Polish components and polishing residues remain on the surface of a wafer subjected to the CMP processing. These polish components and polishing residues need to be removed by a wafer cleaning device. The wafer cleaning device (wafer cleaning unit) is configured to scrub a wafer surface with a sponge member having a roll shape or pencil-like shape while feeding a chemical liquid onto the surface of the wafer making a rotational motion, and rinse off the chemical liquid with a rinse liquid, such as pure water, at the end (Patent literatures 1 and 2).

The wafer cleaning devices disclosed in Patent literatures 1 and 2 are applied mainly to a wiring process (BEOL: back end of line) of forming a multilayer wiring made of copper or another like material. In recent years, due to the necessity of speed-up of logic devices and cost reduction of memory devices, the chemical mechanical polishing is increasingly applied to a transistor process (FEOL: front end of line) of forming a switching circuit. As compared to the BEOL process, the FEOL process forms more minute film thickness, wiring width, and wire intervals, and therefore needs to be improved in performance of removing particulate contaminants, molecular contaminants, and metallic element contaminants. As means for achieving such improvement, a cleaning method that harnesses the acceleration of chemical action which is by heating a chemical liquid is highly expected. A cleaning device used for such cleaning is provided with a vapor-water separator (also referred to as a vapor-liquid separator) that carries out the vapor-water separation of exhaust gas (Patent Literatures 3, 4 and 5).

### CITATION LIST

### PATENT LITERATURE

PTL 1: Japanese Unexamined Patent Application Publication No. 2002-043267

PTL 2: Japanese Unexamined Patent Application Publication No. 2010-074191

PTL 3: Japanese Unexamined Patent Application Publication No. 2003-124180

PTL 4: Japanese Unexamined Patent Application Publication No. 2002-222791

PTL 5: Japanese Unexamined Patent Application Publication No. 2024-65869

### SUMMARY OF INVENTION

### TECHNICAL PROBLEM

The cleaning method that harnesses the acceleration of chemical action which is caused by heating a chemical liquid generates vapor inside a cleaning module due to the use of the heated chemical liquid. When the atmosphere containing this vapor is discharged, there is a possibility that a vapor-separator fails to sufficiently separate liquid from exhaust air, and the vapor is then refrigerated on an exhaust duct surface to cause dew condensation. The dew condensation thus caused might bring a risk of liquid leakage from an exhaust duct joint (for example, a connect portion between the exhaust duct of the cleaning module and the exhaust duct located outside the cleaning module or between the exhaust duct located outside the cleaning module and an exhaust duct main pipe of equipment) or the like. The vapor is considered to contain a chemical liquid component in some cases and might cause negative impacts on the human body when the human is exposed to the leaked liquid. Furthermore, when liquid collects in the exhaust duct due to dew condensation, exhaust pressure is reduced, which decreases the exhaust volume of the cleaning module. This might result in a deterioration in cleaning performance.

An object of the present invention is to restrain dew condensation from occurring within an exhaust duct of equipment that uses a wafer processing apparatus configured to process a wafer with liquid.

### SOLUTION TO PROBLEM

One embodiment discloses a dehumidifying module disposed downstream of a processing module that processes a wafer with liquid, the dehumidifying module including a cooling tank connected to a downstream side of the processing module, a heat exchanger disposed inside the cooling tank, a jet cooler, and a first cold air pipe connecting a refrigerant inlet of the heat exchanger and a cold air outlet of the jet cooler.

### BRIEF DESCRIPTION OF DRAWINGS

FIG. 1 is a schematic plan view of a wafer processing apparatus comprising a wafer processing unit according to one embodiment.

FIG. 2 is a schematic sectional view of a wafer processing unit according to one embodiment.

FIG. 3 is a schematic lateral view of the wafer processing unit according to one embodiment.

FIG. 4 shows a configuration example of a dehumidifying module according to one embodiment.

FIG. 5 shows a configuration example of a dehumidifying module according to one embodiment.

### DESCRIPTION OF EMBODIMENTS

Embodiments of a wafer processing apparatus and a dehumidifying module according to the invention will be explained below with reference to the attached drawings. In the attached drawings, the same or similar elements are provided with the same or similar reference signs. In the explanation of each embodiment, duplicate descriptions about the same or similar elements might be omitted. Features which are mentioned in each embodiment are also applicable to other embodiments without contradicting each other.

### Polishing apparatus

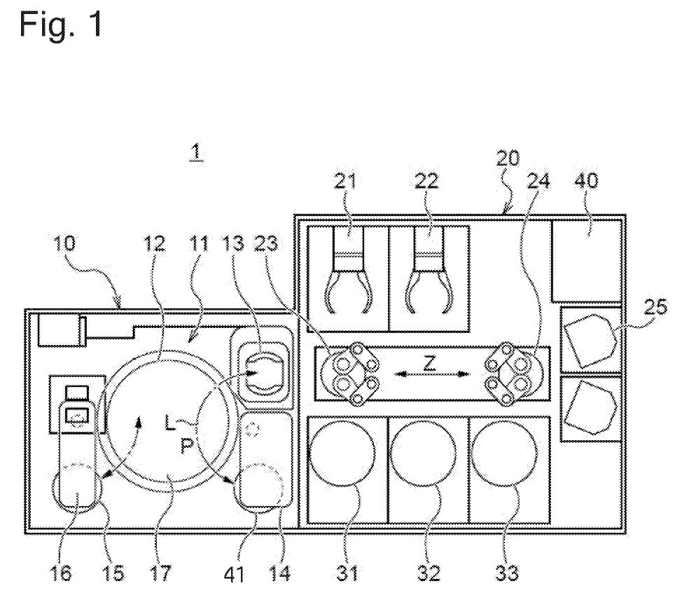

FIG. 1 is a schematic plan view of a wafer processing apparatus comprising a wafer processing unit according to one embodiment. As an example of a wafer processing apparatus, a polishing apparatus 1 that is a chemical mechanical polishing apparatus will be explained here. The invention is applicable not only to polishing apparatus but to freely-selected wafer processing apparatus.

As illustrated in FIG. 1, the polishing apparatus 1 comprises a polishing portion 10 and a cleaning portion 20. Disposed in the polishing portion 10 are a polishing module 11 and a workpiece receiving/delivering device 13 that receives and delivers a wafer Wf. The polishing module 11 is so configured that a turntable 12 is placed at a center; a polishing head 14 to which a top ring 41 is attached is disposed at one side of the turntable 12; and a dressing unit 16 to which a dressing tool 15 is attached is disposed on the other side of the turntable 12. In the cleaning portion 20, two transfer robots 23 and 24 which are movable in directions of arrows Z are disposed at a center; a preliminary wafer cleaning unit 31, a secondary wafer cleaning unit 32, and a spin dryer device 33 with a cleaning function are disposed in parallel on one side of the transfer robots 23 and 24; and two workpiece inverting machines 21 and 22 that invert the wafer Wf are disposed on the other side of the transfer robots 23 and 24.

The polishing apparatus 1 includes a control device (controller) 40 configured to control each portion of the device. The control device 40 includes a memory that stores predetermined programs and a CPU that executes the programs stored in the memory. A storage medium configuring the memory may include an involatile and/or volatile storage medium. Some or all functions of the control device 40 may be configured by hardware, such as an ASIC. Some or all functions of the control device 40 may be configured by a sequencer. The control device 40 partially or entirely may be disposed in the inside and/or outside of a housing of the polishing apparatus 1. The control device 40 is partially or entirely connected to each portion of the polishing apparatus 1 to be communicable by wire and/or air.

Wafers Wf are individually ejected by a transfer robot 24 from a cassette 25 in which prepolished wafers Wf are stored. Each wafer Wf is transferred to the workpiece inverting machine 22 to be inverted, so that a to-be-polished surface (for example, a surface on which a circuit pattern is formed) of the wafer Wf faces downward. The wafer Wf is then transferred from the workpiece inverting machine 22 to the transfer robot 23 and transferred to a workpiece receiving/delivering device 13 of the polishing portion 10.

The wafer Wf on the workpiece receiving/delivering device 13 is held on a lower surface of the top ring 41 of the polishing head 14 and moved onto the turntable 12 as shown by arrows L. The wafer Wf is brought into contact with a polishing surface 17 (for example, a polishing surface of a polishing pad on the turntable 12) to be polished while the top ring 41 and the turntable 12 are being rotated. At this point of time, abrasive liquid (slurry) is fed onto the polishing surface 17 through an abrasive liquid feed pipe, not shown. The wafer Wf, after being polished, is returned to the workpiece receiving/delivering device 13 and delivered to the workpiece inverting machine 21 by the transfer robot 23. The wafer Wf is rinsed with a rinse liquid and then carried to the primary wafer cleaning unit 31 by the transfer robot 23.

In the wafer cleaning unit 31, roll-type cleaning members in a rotating state are brought into abutment with upper and lower surfaces of the wafer Wf that is being rotated by a top of a spindle. A cleaning liquid is injected from a cleaning liquid nozzle, to thereby remove particles attached to the upper and lower surfaces of the wafer Wf and rinse off the particles with the cleaning liquid. The wafer Wf cleaned at the wafer cleaning unit 31 is carried from the wafer cleaning unit 31 to the wafer cleaning unit 32 by the transfer robot 23.

The wafer cleaning unit 32 is so configured that the wafer Wf is grasped at an outer periphery thereof by a chuck of a rotation chuck mechanism. In this state, the entire rotation chuck mechanism is rotated at high speed. During the rotation, a pencil-type cleaning member in a rotating state is brought into abutment with the upper and/or lower surface of the wafer Wf in a rotating state. The cleaning liquid is fed from the cleaning liquid nozzle onto the upper and/or lower surface of the wafer Wf, and simultaneously, the pencil-type cleaning member is oscillated, to thereby clean the wafer Wf.

The wafer Wf cleaned by the wafer cleaning unit 32 is transferred by the transfer robot 24 to a spin dryer device 33 with a cleaning function (spin-rinse dryer). The spin dryer device 33 is so configured that the wafer Wf is cleaned while being rotated and then rotated at high speed to be spin-dried. The wafer Wf, after being dried, is returned to the cassette 25 by the transfer robot 24.

### Wafer Cleaning Unit

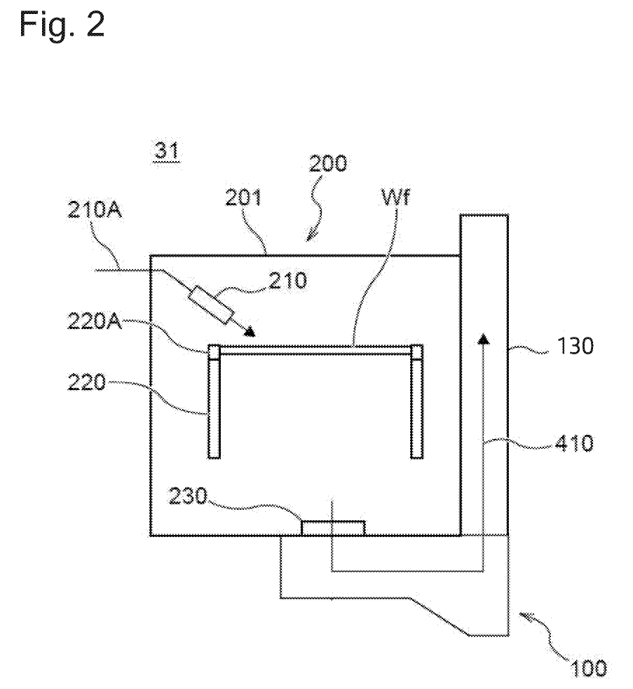

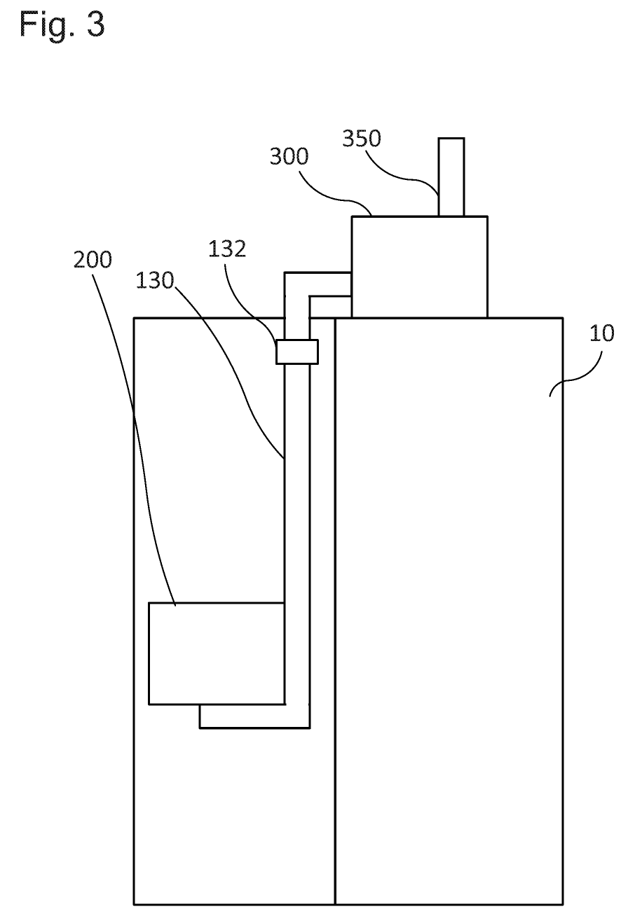

FIG. 2 is a schematic sectional view of a wafer processing unit according to one embodiment. FIG. 3 is a schematic lateral view of the wafer processing unit according to one embodiment. A wafer cleaning unit 31 will be explained here as an example of a wafer processing unit. The wafer cleaning unit 31 and the wafer cleaning unit 32 include respective cleaning modules 200, the interior portions thereof differ in detailed configuration from each other. Nevertheless, the wafer cleaning units 31 and 32 share a common method of processing exhaust air from the cleaning modules 200, so that the explanation on an embodiment which refers to the wafer cleaning unit 31 as an example is also readily applicable to the wafer cleaning unit 32. The invention is applicable not only to wafer cleaning units but to any wafer processing units as long as the units processes wafers with liquid and discharges the atmosphere containing liquid vapor.

In the embodiment illustrated in FIG. 2, the wafer cleaning unit 31 comprises the cleaning module 200 and a gas-liquid separation tank 100. The cleaning module 200 comprises a tank body 201, a rotation mechanism configured to rotate the wafer Wf within the tank body 201 (for example, a plurality of spindles 220 comprising tops 220A that hold an outer peripheral portion of the wafer Wf), a cleaning nozzle 210 configured to feed a cleaning liquid (chemical liquid, pure water, and the like) as a processing liquid onto the upper and/or lower surface of the wafer Wf, and an exhaust outlet 230 configured to discharge the atmosphere (containing the vapor of the cleaning liquid) in the tank body 201. As for the wafer cleaning unit 32, the rotation mechanism is the rotation chuck mechanism (mentioned above) comprising the chuck that grasps the outer periphery of the wafer Wf using the chuck of the rotation chuck mechanism. A line 210A represents a line/pipe for feeding a heated cleaning liquid or other liquids to the cleaning nozzle 210. For the sake of explanation, FIG. 2 only shows some configurations of the cleaning module 200 and omits other detailed configurations.

The gas-liquid separation tank 100 is attached to a bottom surface of the cleaning module 200 so that an upstream side of the gas-liquid separation tank 100 is in fluidic communication with the exhaust outlet 230 of the cleaning module 200. An exhaust duct 130 is attached to a side surface of the cleaning module 200 so that a downstream side of the gas-liquid separation tank 100 is in fluidic communication with an upstream side of the exhaust duct 130. An arrow 410 in FIG. 2 shows an exhaust air flow from the cleaning module 200. As illustrated in FIG. 3, a downstream side of the exhaust duct 130 is connected to a dehumidifying module 300. The gas-liquid separation tank 100 may be configured in any manner, and a conventional gas-liquid separation tank 100 may be employed. According to one embodiment, the gas-liquid separation tank 100 does not necessarily have to be used.

As illustrated in FIG. 3, the dehumidifying module 300 is disposed on a ceiling side of the polishing portion 10. The dehumidifying module 300 does not necessarily have to be disposed on the polishing portion 10 as long as the dehumidifying module 300 is disposed on the ceiling side of the polishing apparatus 1 or wafer processing apparatus in which the dehumidifying module 300 is installed. The dehumidifying module 300 may be disposed on the cleaning module 200 or another processing module. In the embodiment illustrated in the figure, the dehumidifying module 300 is connected to the exhaust duct 130 of the gas-liquid separation tank 100. However, the cleaning module 200 and the dehumidifying module 300 may be connected together by connecting the exhaust duct 130 to the exhaust outlet 230 of the cleaning module 200 without the gas-liquid separation tank 100. According to one embodiment, as illustrated in FIG. 3, a differential pressure gauge 132 is disposed in the exhaust duct 130. The differential pressure gauge 132 is used to detect differential pressure in the exhaust duct 130, which makes it possible to detect a reverse flow in the exhaust duct 130.

### Dehumidifying module

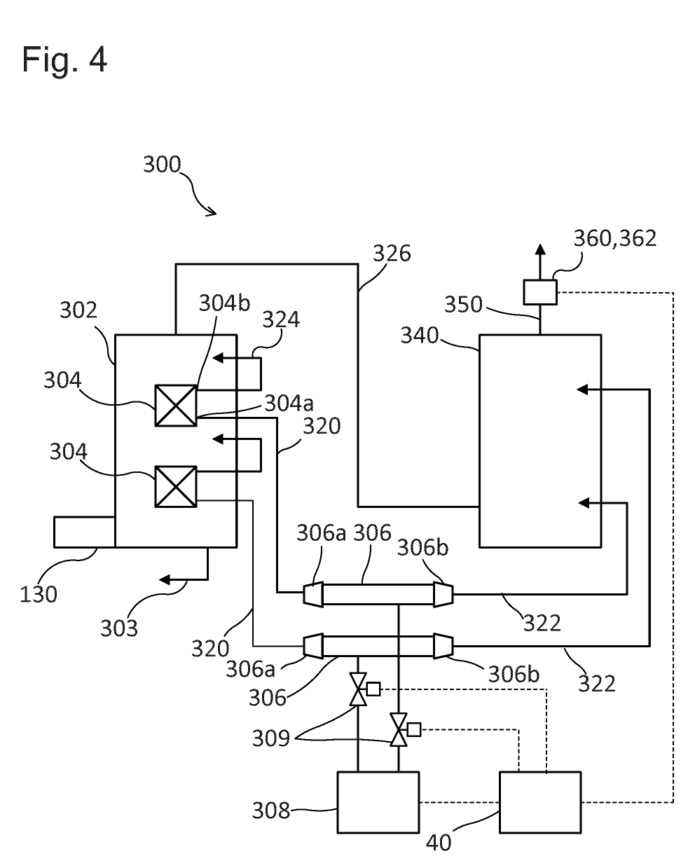

FIG. 4 shows a configuration example of a dehumidifying module 300 according to one embodiment. In one embodiment, the dehumidifying module 300 comprises a cooling tank 302. The cooling tank 302, as described above, is connected to a downstream side of the gas-liquid separation tank 100 through the exhaust duct 130. As already mentioned, in one embodiment, the cleaning module 200 and the cooling tank 302 may be directly connected together, instead of providing the gas-liquid separation tank 100.

The dehumidifying module 300 comprises a heat exchanger 304 disposed in an interior portion of the cooling tank 302. The heat exchanger 304 may be a freely-selected heat exchanger that is capable of refrigerating or heating a surrounding environment by use of a refrigerant. As one embodiment, the heat exchanger 304 may be so configured that the refrigerant can pass through an interior portion of a metal coil having a high heat conductivity. The exhaust air containing vapor from the cleaning module 200 is refrigerated by the heat exchanger 304, to thereby accelerate dew condensation within the cooling tank 302 and remove liquid from the exhaust air.

In one embodiment, the dehumidifying module 300 comprises a jet cooler 306. The jet cooler 306 is a cold air generator that applies the principles of the vortex theory, has no movable portion, and does not use a refrigerant or electricity. Connected to the jet cooler 306 is a compressed air source 308. The compressed air source 308 is configured to be capable of feeding dried compressed air to the jet cooler 306. In one embodiment, the jet cooler 306 is capable of generating cold air having a temperature of about -30°C and warm air having a temperature of about 50°C out of the compressed air having room temperature.

In one embodiment, an electromagnetic valve 309 is disposed in a pipe connecting the compressed air source 308 and the jet cooler 306. The compressed air to be fed to the jet cooler 306 may be controlled in flow rate by operating the electromagnetic valve 309 using the control device 40. Using the cold air from the jet cooler 306 as a refrigerant for the heat exchanger 304, the present embodiment only uses the dried compressed air as a refrigerant and does not require a special refrigerant, such as chlorofluorocarbon. The use of the compressed air as a refrigerant eliminates the necessity of a chiller that is required when cooling water is used with a refrigerant, thereby leading to reduction of consumed power. A drainage pipe 303 is connected to a bottom portion of the cooling tank 302, which makes it possible to discharge the liquid condensed in the cooling tank 302 from the cooling tank 302.

As illustrated in FIG. 4, a cold air outlet 306a of the jet cooler 306 and a refrigerant inlet 304a of the heat exchanger 304 are connected together through a first cold air pipe 320. A refrigerant outlet 304b of the heat exchanger 304 is connected to one end of a second cold air pipe 324. In one embodiment, the other end of the second cold air pipe 324 is connected to the interior portion of the cooling tank 302. This makes it possible to feed into the cooling tank 302 the cold air from the jet cooler 306 which is used as a refrigerant in the heat exchanger 304. Since the dried cold air from the jet cooler 306 is fed into the cooling tank 302, it is possible to attenuate the exhaust air containing vapor and decrease moisture. In one embodiment, the cold air that passes through the second cold air pipe 324 may be discharged outside the cooling tank 302, instead of being fed into the cooling tank 302. The cold air that passes through the second cold air pipe 324 may also be only partially fed into the cooling tank 302, and the rest of the cold air may be discharged outside the cooling tank 302. In the embodiment illustrated in FIG. 4, the heat exchanger 304 and the jet cooler 306 comprise two heat exchangers 304 and two jet coolers 306, respectively. However, the number of heat exchanges 304 and the number of jet coolers 306 may be freely selected, and therefore may be one or more.

In one embodiment, as illustrated in FIG. 4, the dehumidifying module 300 comprises a heating tank 340. As illustrated in the figure, the cooling tank 302 and the heating tank 340 are connected together through a connecting pipe 326. As illustrated in the figure, a warm air outlet 306b of the jet cooler 306 is connected to one end of a warm air pipe 322, and the other end of the warm air pipe 322 is connected to the heating tank 340. This makes it possible to feed warm air from the jet cooler 306 to the heating tank 340. The feeding of the dried warm air from the jet cooler 306 to the heating tank 340 makes it possible to attenuate exhaust air and further decrease moisture. As one embodiment, the invention may be so configured that the warm air from the jet cooler 306 is only partially fed to the warning tank 340. In the embodiment illustrated in the figure, the heating tank 340 is connected to a heating tank outlet pipe 350. A downstream side of the heating tank outlet pipe 350 is connected, for example, through an exhaust duct that is a flexible tube, not shown, to an exhaust duct main pipe of equipment in which the polishing apparatus 1 or the wafer processing apparatus is used.

In one embodiment, as illustrated in FIG. 4, the heating tank outlet pipe 350 comprises a thermometer 360 and/or a hygrometer 362. The thermometer 360 and/or the hygrometer 362 is connected to the control device 40. In one embodiment, the control device 40 is capable of controlling the operation of the jet cooler 306 on the basis of measurement results of the thermometer 360 and/or the hygrometer 362. For example, the control device 40 is capable of controlling the flow rate of the compressed air to be fed to the jet cooler 306 through the electromagnetic valve 309 on the basis of the measurement results of the thermometer 360 and/or the hygrometer 362. As an example, if the exhaust air passing through the outlet pipe 350 has a humidity higher than a predetermined value, feedback control may be implicated, which increases the flow rate of the compressed air to be fed to the jet cooler 306 to accelerate the dehumidification of the exhaust air.

In one embodiment, the dehumidifying module 300 may be so configured that an outlet of the cooling tank 302 is connected to the outlet pipe 350 without the heating tank 340 mentioned above. In one embodiment, one dehumidifying module 300 is provided for the cleaning module 200 or a freely-selected module that processes a wafer using liquid in a wafer processing apparatus. As an example, the polishing apparatus 1 illustrated in FIG. 1 is so configured that the primary wafer cleaning unit 31, the secondary wafer cleaning unit 32, and the spin dryer device 33 with a cleaning function are disposed, each of which may be provided with one dehumidifying module 300.

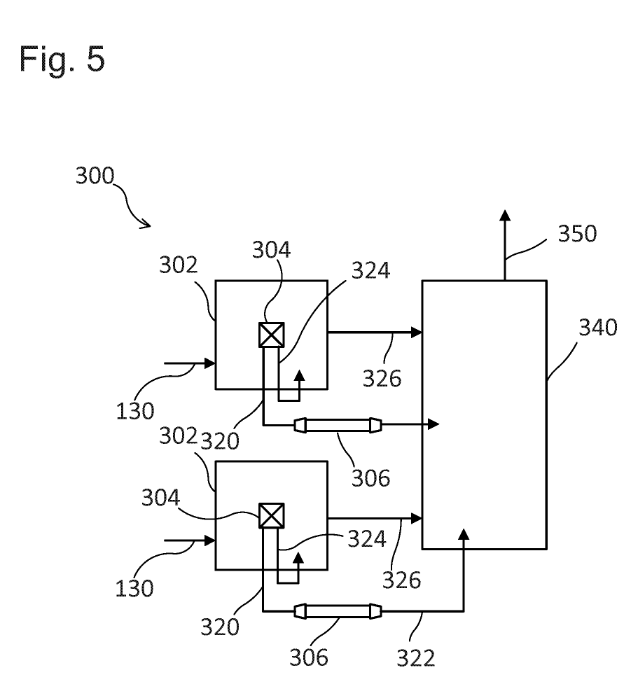

FIG. 5 shows a configuration example of the dehumidifying module 300 according to one embodiment. Although the configuration of the dehumidifying module 300 in FIG. 5 is partially omitted for clarification of the figure, the dehumidifying module 300 may include the freely-selected configuration explained above with reference to FIG. 4.

The embodiment illustrated in FIG. 5 comprises two cooling tanks 302. One heat exchanger 304 is disposed in each of the cooling tanks 302. The two cooling tanks 302 are connected to exhaust ducts 130 extending from cleaning modules 200, respectively. As an example, one of the two cooling tanks 302 may be connected to the exhaust duct 130 extending from the primary wafer cleaning unit 31, and the other to the exhaust duct 130 extending from the secondary wafer cleaning unit 32.

The dehumidifying module 300 illustrated in FIG. 5 comprises two jet coolers 306. The dehumidifying module 300 is so configured that cold air from the jet coolers 306 can be fed to the heat exchangers 304 of the cooling tanks 302. In the embodiment illustrated in FIG. 5, the cooling tanks 302, the heat exchangers 304, and the jet coolers 306 may have the freely-selected configurations explained above with reference to FIG. 4.

The dehumidifying module 300 illustrated in FIG. 5 comprises one heating tank 340. As illustrated in FIG. 5, the two cooling tanks 302 are connected to the heating tank 340 through respective connecting pipes 326. Furthermore, as illustrated in FIG. 5, the dehumidifying module 300 is so configured that warm air from the jet coolers 306 is fed to the heating tank 340. The heating tank 340 is connected to an outlet pipe 350. The other end of the outlet pipe 350 is connected to an exhaust duct main pipe of equipment in which the polishing apparatus 1 or the wafer processing apparatus is used.

Although the embodiment illustrated in FIG. 5 includes the two cooling tanks 302, the number of the cooling tanks 302 is freely selected. A plurality of cooling tanks 302, the number of which is freely selected, may be connected to one heating tank 340. For example, the number of the cooling tanks 302 may be decided according to the number of wafer processing units that process a wafer using liquid in the wafer processing apparatus or the polishing apparatus 1 and discharge atmosphere containing liquid vapor. The embodiment illustrated in FIG. 5, as well as the embodiment illustrated in FIG. 4, may utilize the thermometer 360 and/or the hygrometer 362 to control the dehumidification of exhaust air using the control device 40 although FIG. 5 omits such configuration for clear illustration.

The following explanation will discuss a flow of dehumidification processing that uses the dehumidifying module 300. The exhaust air containing the vapor discharged from the cleaning module 200 passes through the exhaust outlet 230 and enters the gas-liquid separation tank 100, in which liquid and gas are separated from each other. The exhaust air passes through the exhaust ducts 130 and enters the cooling tanks 302. Even if the exhaust air passes through the gas-liquid separation tank 100, vapor cannot always be removed. In the present embodiment, therefore, the exhaust air is fully dehumidified by the dehumidifying module 300 located downstream. If the gas-liquid separation tank 100 is not provided, the air discharged from the cleaning module 200 enters the cooling tanks 302 through the exhaust ducts 130.

0036 The exhaust air that enters the cooling tanks 302 is refrigerated by the heat exchangers 304. Cold air is fed from the jet coolers 306 through the first cold air pipe 320 to the heat exchangers 304. The cold air that is fed from the jet coolers 306 has, for example, a temperature of about -30°C. When the exhaust air containing vapor is refrigerated in the cooling tanks 302, dew condensation occurs, and moisture is removed from the exhaust air. The liquid condensed in the cooling tanks 302 is discharged from drainage pipes 303. In one embodiment, the dried cold air that is discharged from the jet coolers 306 and passes through the heat exchangers 304 is partially or entirely fed into the cooling tanks 302. Moist exhaust air from the cleaning module 200 is attenuated, and humidity is further decreased. The exhaust air dehumidified in the cooling tanks 302 passes through the connecting pipes 326 and enters the heating tank 340.

The dried warm air discharged from the jet coolers 306 is partially or entirely fed into the heating tank 340 through warm air connecting pipes 322. The exhaust air that enters the heating tank 340 is therefore further attenuated and heated, thereby being further decreased in humidity. The exhaust air heated in the heating tank 340 is discharged through the heating tank outlet pipe 350 to the exhaust duct main pipe of the equipment in which the wafer processing apparatus is used. In one embodiment, the exhaust air discharged from the heating tank 340 through the outlet pipe 350 is measured in temperature and humidity using the thermometer 360 and the hygrometer 362. In one embodiment, the dehumidifying module 300 can be controlled according to measurement results obtained by the thermometer 360 and the hygrometer 362. For example, if an amount of compressed air to be fed to the jet coolers 306 is controlled according to the measurement results obtained by the thermometer 360 and the hygrometer 362 to change an amount of cold air to be fed to the heat exchangers 304 and an amount of warm air to be fed to the warm tank 340, it is possible to control a degree to which the exhaust air is dehumidified in the dehumidifying module 300.

As mentioned above, the use of the dehumidifying module 300 disclosed in the present description removes liquid from exhaust air within the wafer processing apparatus, to thereby reduce the risk of causing dew condensation in the exhaust duct of the equipment in which the wafer processing apparatus is used. In general, the entire exhaust structure of equipment in which a wafer processing apparatus is used often comprises a main pipe (main duct) and branching pipes diverged from the main pipe. The outlet pipe 350 of the dehumidifying module 300 which is disclosed in the present description is connected to such a branching pipe that is diverged from a main pipe. The main and the branching pipes are not necessarily connected with high sealing degree, and there has been a risk that dew condensation occurs within the branching or main pipe if the exhaust air containing vapor enters the branching pipes. The use of the dehumidifying module according to the present disclosure makes it possible to remove liquid from exhaust air within the wafer processing apparatus and reduce the risk of causing dew condensation in downstream pipes.

Several embodiments of the invention have been explained. The foregoing embodiments of the invention are intended to facilitate the understanding of the invention and not to limit the invention. Needless to say, the invention may be modified or improved without deviating from the gist thereof and includes equivalents thereof. The constituent elements mentioned in claims and description may be combined or omitted as long as the aforementioned problem is at least partially solved or as long as the advantageous effect is at least partially provided.

Mode 1 According to Mode 1, there is provided a dehumidifying module disposed downstream of a processing module for processing a wafer with liquid, the dehumidifying module comprising a cooling tank connected to a downstream side of the processing module, a heat exchanger disposed inside the cooling tank, a jet cooler, and a first cold air pipe connecting a refrigerant inlet of the heat exchanger and a cold air outlet of the jet cooler.

Mode 2 According to Mode 2, the dehumidifying module according to Mode 1 comprises a second cold air pipe connecting a refrigerant outlet of the heat exchanger and an interior portion of the cooling tank.

Mode 3 According to Mode 3, the dehumidifying module according to Mode 1 further comprises a heating tank connected to a downstream side of the cooling tank and includes a warm air pipe connecting a warm air outlet of the jet cooler and the heating tank.

Mode 4 According to Mode 4, the dehumidifying module according to Mode 3 further comprises a heating tank outlet pipe connected to an outlet of the heating tank and a thermometer and a hygrometer which are provided to the heating tank outlet pipe.

Mode 5 According to Mode 5, the dehumidifying module according to Mode 4 further comprises a control device for controlling operation of the jet cooler, the control device being connected to the thermometer and the hygrometer, the control device being configured to control the operation of the jet cooler on the basis of measured values of the thermometer and the hygrometer.

Mode 6 According to Mode 6, there is provided the dehumidifying module according to Mode 1, in which a differential pressure gauge is disposed in a pipe connecting the processing module and the cooling tank.

Mode 7 According to Mode 7, the dehumidifying module according to Mode 1 further comprises a second cooling tank connected to a downstream side of a second processing module, a second heat exchanger disposed inside the second cooling tank, a second jet cooler, a 2-1 cold air pipe connecting a refrigerant inlet of the second heat exchanger and a cold air outlet of the second jet cooler, a heating tank connected to a downstream side of the cooling tank and the second cooling tank, a first warm air pipe connecting a warm air outlet of the jet cooler and the heating tank, and a second warm air pipe connecting a warm air outlet of the second jet cooler and the heating tank.

According to Mode 8, there is provided a wafer processing apparatus, the wafer processing apparatus including a cleaning module for cleaning a wafer, and a dehumidifying module according to any one of Modes 1 to 7.

### REFERENCE SIGNS LIST

1 Polishing apparatus

10 Polishing portion

11 Polishing module

31, 32 Wafer cleaning unit

40 Control device (controller)

130 Exhaust duct

132 Differential pressure gauge

200 Cleaning module

300 Dehumidifying module

302 Cooling tank

304 Heat exchanger

304a Refrigerant inlet

304b Refrigerant outlet

306 Jet cooler

306a Cold air outlet

306b Warm air outlet

309 Electromagnetic valve

320 First cold air pipe

322 Warm air pipe

324 Second cold air pipe

326 Connecting pipe

340 Heating tank

350 Waring tank outlet pipe

360 Thermometer

362 Hygrometer

Wf Wafer

What is claimed is:

1. A dehumidifying module disposed downstream of a processing module for processing a wafer with liquid, the dehumidifying module comprising:
a cooling tank connected to a downstream side of the processing module;
a heat exchanger disposed inside the cooling tank;
a jet cooler;, and
a first cold air pipe connecting a refrigerant inlet of the heat exchanger and a cold air outlet of the jet cooler.

2. The dehumidifying module according to claim 1, further comprising a second cold air pipe connecting a refrigerant outlet of the heat exchanger and an interior portion of the cooling tank.

3. The dehumidifying module according to claim 1, further comprising a heating tank connected to a downstream side of the cooling tank,
wherein the dehumidifying module comprises a warm air pipe connecting a warm air outlet of the jet cooler and the heating tank.

4. The dehumidifying module according to claim 3, further comprising:
a heating tank outlet pipe connected to an outlet of the heating tank; and
a thermometer and a hygrometer which are provided to the heating tank outlet pipe.

5. The dehumidifying module according to claim 4, further comprising a control device for controlling operation of the jet cooler,
wherein the control device is connected to the thermometer and the hygrometer, and
wherein the control device is configured to control the operation of the jet cooler on the basis of measured values of the thermometer and the hygrometer.

6. The dehumidifying module according to claim 1,
wherein a differential pressure gauge is disposed in a pipe connecting the processing module and the cooling tank.

7. The dehumidifying module according to claim 1, further comprising:
a second cooling tank connected to a downstream side of a second processing module;
a second heat exchanger disposed inside the second cooling tank;
a second jet cooler;
a 2-1 cold air pipe connecting a refrigerant inlet of the second heat exchanger and a cold air outlet of the second jet cooler;
a heating tank connected to a downstream side of the cooling tank and the second cooling tank;
a first warm air pipe connecting a warm air outlet of the jet cooler and the heating tank, and
a second warm air pipe connecting a warm air outlet of the second jet cooler and the heating tank.

8. A wafer processing apparatus comprising:
a cleaning module for cleaning a wafer, and
a dehumidifying module according to claim 1.
